(19) United States
(12) Patent Application Publication
(10) Pub. No.: US 2025/0192732 A1
(43) Pub. Date: Jun. 12, 2025

(54) INTEGRATED CIRCUIT AC COUPLING DESIGN WITH ADJUSTED-RATIO AND HIGH IMPEDANCE EMITTER FOLLOWER STAGE

(71) Applicant: MACOM Technology Solutions Holdings, Inc., Lowell, MA (US)

(72) Inventors: Duy Nguyen, Lowell, MA (US); Nguyen Nguyen, Lowell, MA (US); Stefano D'Agostino, Los Altos, CA (US); Trong Phan, Lowell, MA (US)

(21) Appl. No.: 18/981,073

(22) Filed: Dec. 13, 2024

Related U.S. Application Data
(63) Continuation-in-part of application No. 17/058,629, filed on Nov. 24, 2020, now Pat. No. 12,184,335.
(60) Provisional application No. 62/678,164, filed on May 30, 2018.

(51) Int. Cl. H03F 1/56; H03F 3/04

(52) U.S. Cl. CPC H03F 1/56; H03F 3/04; H03F 2200/222

(57) ABSTRACT

A system configured as part of an integrated circuit to block DC components from an amplifier comprising a matching network and an emitter follower circuit. The matching comprises an input configured to receive an input signal having a DC component. A voltage divider network comprises at least one resistor, and at least one capacitor. The network receives the signal and DC component and the voltage divider network blocks the DC component to generate a network output signal. The emitter follower (EF) circuit with EF devices configured to process the network output signal to generate an EF circuit output signal on an EF output. A biasing circuit generates a bias signal for the EF device. The bias signal has a value that is controlled by a bias control signal. Aias control signal generator compares the EF circuit output signal to a reference voltage, and generates the bias control signal.

### 1. FIELD OF THE INVENTION

The invention relates to AC coupling topology, and in particular to an AC coupling arrangement located on an integrated circuit.

### 2. RELATED ART

Optical communication systems are commonly found in data centers and for long haul applications to transmit data at high data rates between two locations. Foundational to optical communication systems is the data to be transmitted, and a driver amplifier which amplifies a modulated signal onto an optical modulator. The interface between the data source and the driver must block DC signal components for preferred operation. This is typically achieved through use of an off-chip blocking capacitor.

FIG. 1A illustrates a block diagram of an example environment of use, namely, an optic signal transmitter. This is but one possible environment of use and it is contemplated that other environments of use are possible. As shown in FIG. 1A, a data source 104 supplies data for transmission over an optic fiber 108. In one embodiment, the data source is a DSP. To achieve biasing of a driver, a supply voltage source 112 is provided to deliver power to the system. The supply voltage source 112 may be any source including a hard wire utility supplied power, power supply, battery, or any other source. The supply voltage source 112 provides a supply voltage to a bias circuit (part of the driver amplifier 120), which in turn provides a bias voltage to a driver amplifier 120. The driver amplifier 120 also receives the data to be transmitted in optic format from the data source 104. The driver amplifier 120 includes one or more amplifiers configured to amplify and modulate the data to a level suitable for driving an optical modulator or laser diode 124. Responsive to the signal from the driver, the optical modulator or laser diode 124 generates the optic signal 128, which is presented to the fiber optic cable 108, for transmission to a remote location, such as for example another device in a data center or to a remote location in long haul applications. The frequency range of operation can be as high as several tens of Gigahertz (e.g. 50 GHz) or higher, and as low as 100 KHz.

FIG. 1B illustrates a block diagram of the interface between the data source 104 and the driver amplifier 120 that includes DC blocking capacitors. In this embodiment, there are four channels (C1, C2, C3, C4), and each channel is a differential pair 170 comprising two conductive paths, namely a positive path 174 and a negative path 176. In series in each path is a DC blocking capacitor 182 as shown. The blocking capacitors 182 function to block DC components from the signal passing from the data source 104 to the driver amplifier 120. In addition, the capacitance has to be large enough to allow the lowest frequency of operation in (e.g., 1 MHz or 100 KHz in various embodiments) without attenuating it. Furthermore, the capacitor needs to have low parasitics so as to not influence the high frequency content.

Because of the aforementioned, blocking capacitors are typically external to the integrated circuit causing surface mount components to be used. As a drawback to the prior art, the blocking capacitors are large in size due to the requirement that the blocking capacitor block DC signal components yet the low pass frequency is 1 MHz. Due to the blocking capacitors being external to the integrated circuits which form the data source, the blocking capacitors are undesirably large in size. In some embodiments, the capacitor may be as large as the integrated circuit dedicated to the channel associated with the blocking capacitors. Because of the size of the blocking capacitors, the components have a large footprint consuming valuable real estate on the circuit board in contrast to technological trends, which are towards smaller and more compact—not larger—configurations.

Another downside to external blocking capacitors is that high fidelity surface mount components with good frequency performance carries a premium in cost. With the differential inputs and four channels shown in FIG. 1B, eight capacitors are needed. Example sizes for these blocking capacitors are 100 nano-farad capacitance and costs range between one to two dollars each, or up to sixteen dollars for all four channels. This further increases the space requirements and increases costs, which is then passed onto the customers and/or reduces profit. Another drawback is that these capacitors add to manufacture costs and can increase the failure rate due to the additional components. Any component outside of the integrated circuit requires transitions, transmission lines to connect to the component, and an assembly process leading to more parasitics, degraded performance, and increases assembly complexity.

### SUMMARY

To overcome the drawbacks of the prior art and provide additional benefits, a capacitive coupling system is disclosed. In one embodiment the system is configured as part of an integrated circuit to block DC components from an amplifier comprising. The system includes an input configured to receive an input signal such that the input signal has a DC component. A voltage divider network which has an input, an output, at least one resistor and at least one capacitor is also provided. The input is configured to receive the signal having a DC component such that the voltage divider network blocks the DC component. An amplifier is provided which has an input connected to the output of the voltage divider network.

In one configuration, the voltage divider network comprises a first impedance element and a second impedance element. As such, the first impedance element and the second impedance element may comprise a resistor in series with a capacitor. In one embodiment, the amplifier includes a biasing element and the biasing element is configured to receive the input signal without the DC component. The biasing element includes a first resistor connected to a supply voltage and a second resistor connect to ground.

The capacitive coupling system may be configured for differential signals and the system thus far described is associated with a positive path. The system may further comprise a negative path input configured to receive a negative path signal which has a DC component connected. This system also includes a negative path first impedance element having an input and an output. The input is configured to receive the negative path signal having a DC component such that the negative path first impedance element blocks the DC component. The negative path also includes a second impedance element configured to connect between the output of the negative path first impedance matching element and a ground node. The negative path second impedance element, when combined with the negative path first impedance element, forms a voltage divider network. An impedance matching element is provided and connected between the input of the positive path and the negative path input. The impedance matching element is configured to match an input impedance of the amplifier to a data source. The impedance matching element may be formed from one or more resistors connected in series between the input of the positive path and the negative path input and a capacitor connected to ground.

Also disclosed herein is a capacitive coupling system configured as part of an integrated circuit for a differential pair to couple differential inputs to an amplifier. In one embodiment, the system comprises a positive path and a negative path. The positive path includes an input configured to receive a positive path input signal such that the positive path input signal has a DC component. Also part of the positive path is a first impedance element having an input and an output, the input is configured to receive the positive path input signal such that the first impedance element blocks the DC component. Also part of the positive path is a second impedance element configured to connect between the output of the first impedance matching element and a ground. The second impedance element, when combined with the first impedance element, forms a voltage divider network. An amplifier is provided which has an input connected to the output of the positive path first impedance element. The negative path includes an input configured to receive a negative path input signal which has a DC component. Also part of the negative path is a first impedance element having an input and an output. The input is configured to receive the negative path input signal such that the first impedance element blocks the DC component. A second impedance element is also provided and configured to connect between the output of the first impedance matching element and ground. The second impedance element when combined with the first impedance element forms a voltage divider network. The amplifier has an input connected to the output of the negative path first impedance element. Also part of this system is an impedance matching element connected between the positive path input and the negative path input. The impedance matching element configured to match an input impedance of the amplifier to a data source.

In one embodiment, the positive path first impedance element comprises at least resistor and at least one capacitor. It is contemplated that the at least one resistor and the at least one capacitor are in series. In one configuration, the positive path second impedance element comprises at least resistor and at least one capacitor. The positive path second impedance element, at least one resistor, and the at least one capacitor may be in series and connect to a ground node.

It is contemplated that the impedance matching element may comprise at least one resistor and at least one capacitor, such that the capacitor is connected to ground. In this embodiment, the at least one resistor comprises two resistors connected in series between the positive path input and the negative path input forming a middle node between the two resistors and the capacitor connects to the middle node and to ground.

Also disclosed is a method for coupling an input signal, connected a data source, to a driver and blocking DC components of an input signal. This method includes receiving the input signal from a data source such that the input signal has a DC component. This method also provides the input signal to a first impedance element. The first impedance element is configured as part of an integrated circuit. Next, blocking the DC component of the input signal with the first impedance element and then providing an output from the first impedance element to a second impedance element. The second impedance element configured as part of the integrated circuit. This method also establishes the input impedance with the second impedance element and the first impedance element to create an impedance matched signal, and then provides the impedance matched signal to the driver.

In one embodiment, the input signal is a differential signal pair comprising a first signal on a first path and a second signal on a second path, the second path generally identical to the first path. The first and second path each have the first impedance element and the second impedance element and this embodiment further comprises matching the input impedance of the driver to the data course with an impedance matching element connected between the first path and the second path.

In one configuration, the first impedance element and the second impedance element each comprise at least one resistor and at least one capacitor. It is contemplated that the impedance matching element may comprise an interconnect between the first path and the second path, the interconnect having two or more resistors in series and a capacitor connect ground from the interconnect to ground. In one embodiment, this method does not include blocking DC components with a capacitor, external to the integrated circuit, located between the data course and the driver. This method may further comprise biasing the driver with a biasing element such that the DC components are blocked from the biasing element by the first impedance element.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The components in the figures are not necessarily to scale, emphasis instead being placed upon illustrating the principles of the invention. In the figures, like reference numerals designate corresponding parts throughout the different views.

FIG. 1A is a block diagram illustrating an example environment of use of the innovation disclosed herein.

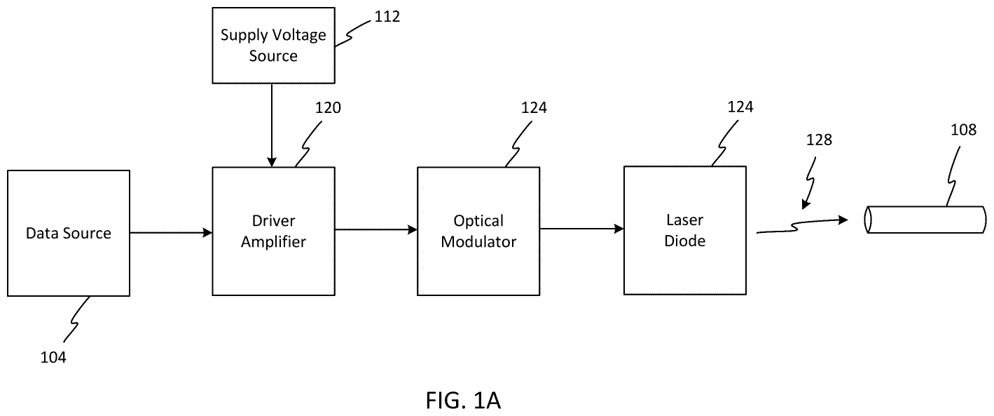

FIG. 1B is a block diagram showing the coupling capacitors.

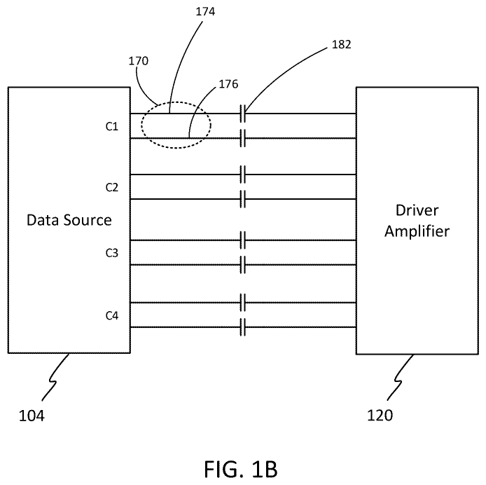

FIG. 2A is a block diagram of an example embodiment of an integrated circuit located coupling capacitor arrangement for a differential signal.

FIG. 2B is a block diagram of an example embodiment of an integrated circuit located coupling capacitor arrangement for a single ended signal.

FIG. 3A is a circuit diagram of an integrated circuit located coupling capacitor arrangement for a differential signal.

FIG. 3B is a circuit diagram of an integrated circuit located coupling capacitor arrangement for a single ended signal.

FIG. 4 illustrates signal plots of a signal and return loss.

FIG. 5 illustrates an example embodiment of a coupling network that achieves the benefits described above when combined with the emitter follower stage.

FIG. 6 illustrates an exemplary emitter follower circuit with an internal biasing circuit, collectively configured to follow the matching network of FIG. 5.

FIG. 7 illustrates a generalized block diagram of a single-ended version of the circuit of FIG. 6.

### DETAILED DESCRIPTION

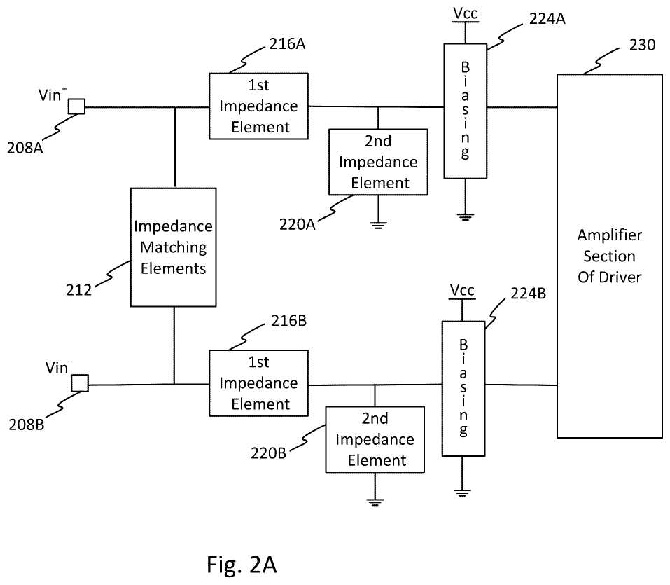

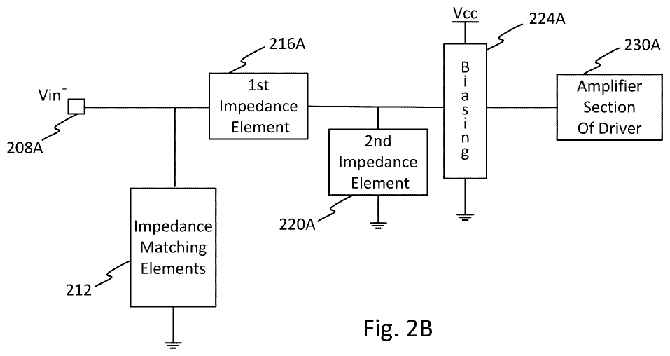

FIG. 2A illustrates a block diagram of a capacitor coupling system that avoids use of external blocking capacitors. This is but one possible block diagram configuration and it is contemplated that other arrangement of elements are possible that do not depart from the claimed innovation or the scope of the improvement over the prior art. This is a differential pair configuration, and as such, the upper signal path is discussed in detail. The lower signal path is generally identical and symmetric to the upper path. As shown, two inputs Vin⁺ 208A and Vin⁻ 208B are shown to receive the incoming differential signal. Connected to each of the input terminals 208A, 208B are one or more impedance matching elements 212. In one embodiment, these elements comprise one or more resistors and one or more capacitors. In other embodiments, other elements may be included or left out. The impedance matching element 212 is configured to match the input impedance of the driver amplifier 120 to the data source 104 providing the signals to the inputs Vin⁺ 208A and Vin⁻ 208B to avoid reflection and minimize return loss. In some embodiments the input impedance may be 50 ohms. The input impedance seen at Vin⁺ 208A depends on the combination of the impedance matching elements 212 as well as the 1^{st} impedance element 216A and 2^{nd} impedance element 220A, and these three elements are tuned together to provide a desired through-response and input impedance.

Also connected to input Vin⁺ 208A is a first impedance element 216A. The output of the first impedance element 216A connects to a second impedance element 220A and a biasing element 224. The opposing terminal of the second impedance element 220A connects to ground. The first impedance element 216A and the second impedance element 220A form an impedance network, specifically a voltage divider or capacitor divider. The combination of the first impedance element 216A and the second impedance element 220A, both of which when combined as shown replace the large external blocking capacitor (also referred to as a coupling capacitor). Silicon is much more economical thus, integrating the blocking capacitor with the silicon driver lowers the total cost, as well as the size.

The input signal presented to the input Vin⁺ passes through the first capacitive element 216A toward the second capacitive element 220A. A portion of the input signal passes to ground through the second capacitive element 220A. The capacitors 216A appear as an open circuit to DC components of the input signal thereby blocking unwanted DC signal components from reaching and possibly disrupting the biasing element of the amplifier section of the driver. The capacitor divider network 216A, 220A works across all frequencies. For example, defining the first impedance element 216A as Z1 and the second impedance element 220A as Z2, the following equation defines the output of the capacitance divider network: Vout=Z2/(Z1+Z2). When Z1=Z2, this equation can reduce to Z2/2Z2 which can be further reduced to ½. Fundamental to this invention is the idea of a capacitive divider, which in its ideal form works at all frequencies except for exactly DC. The math behind a capacitive divider shows that the impedance of a capacitor across frequency is Z=−j/[2*π*f*C]. Therefore the above example could be written as

$$V out = V in * \frac{Z 2}{Z 1 + Z 2} = Vin * \frac{- \frac{j}{2 * π * f * C 2}}{- \frac{j}{2 * π * f * C 1} + - \frac{j}{2 * π * f * C 2}} = V in * \frac{\frac{1}{C 2}}{\frac{1}{C 1} + \frac{1}{C 2}} = V in * \frac{C 1}{C 1 + C 2}$$

As can be seen in the final equation, Vout depends only on the ratio of capacitances and is therefore frequency independent, which means that ideally this circuit works as low as DC (excluding exactly DC which is undefined). Moreover, note that the actual size of the capacitor is not critical—the ratio of the capacitance is what matters. For example, if C1=C2=100 nF the ratio becomes ½. However, even if C1=C2=1 pF the ratio would still be ½. Both would pass all frequencies except DC equally well. Thus, whereas in an external blocking capacitor as a single element would need to be greater than 100 nF for sub 1 MHz operation, the capacitor divider topology as a ratio integrated on chip can achieve the same low frequency performance with a much smaller capacitance value. In practice, parasitics in the capacitors and the load on the output of the capacitive divider limit how low the capacitive divider works. However, modern semiconductor processes allow this network to work well below 1 MHz.

The biasing element 224 connects to a supply voltage Vcc and a ground terminal to provide biasing to amplifier section 230 of the driver. Any DC signal components received on the input 208A, 208B can interfere with the biasing element output or vice versa interfere with data source 104. As a result, it is preferable to block DC components with the AC coupling capacitor (also referred to as a DC blocking capacitor). Biasing elements 224A, 224B are generally known and as such are not described in detail herein. The output of the biasing element 224A connects to an amplifier section 230 of the driver 120. The amplifier section 230 amplifies the signal to a level suitable for driving the optic modulator and optic signal generator, such as a laser or diode. Although shown as a single amplifier, it is contemplated that each path (upper path and lower path) may have a separate amplifier. The lower path is generally similar to the upper path and as such is not described in detail.

FIG. 2B is a block diagram of an example embodiment of an integrated circuit located coupling capacitor arrangement for a single ended signal. As compared to FIG. 2A, similar elements are labeled with identical reference numbers. This embodiment is a single-ended configuration and as such, a single input 208A is provided. The impedance matching elements 212 may comprise any combination of elements, active or passive, to match the input impedance of driver to a data source. In other embodiments, other single ended configurations are possible that also benefit from an integrated voltage divider network that blocks DC signal components to avoid use of external capacitors.

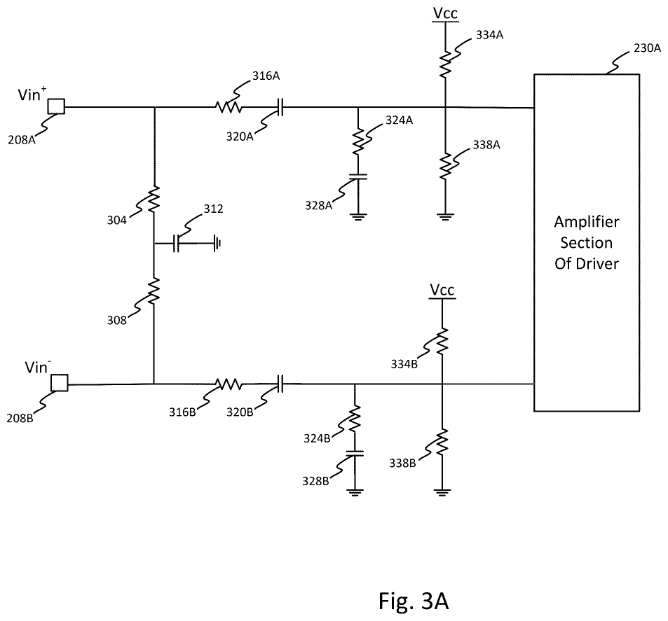

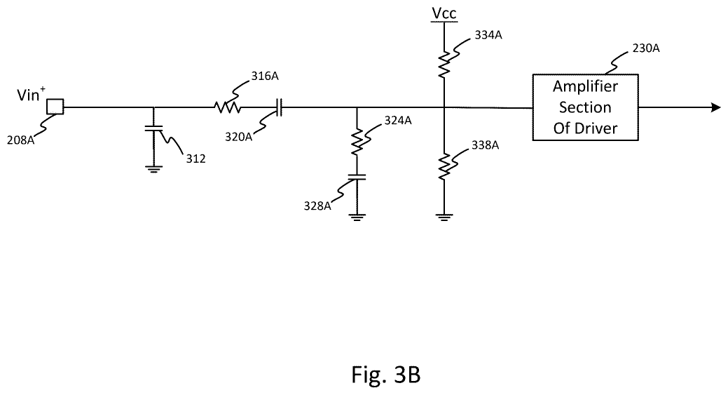

FIG. 3A illustrates one example embodiment of a circuit diagram of FIG. 2A. This is but one possible circuit level configuration and it is contemplated that other embodiments and configurations are possible that do not depart from the scope of the invention. In this embodiment, the input Vin⁺ 208A connects to a first impedance matching resistor 304 and resistor 316A. The opposing terminal of impedance matching resistor 304 connects to a second impedance matching resistor 308 and a capacitor 312. The opposing terminal of the second impedance matching resistor 308 connects to the lower signal path, which is configured generally similar to or identical to the upper signal path.

The opposing terminal of resistor 316A connects in series with a capacitor 320A. The capacitor 320A opposing terminal connects to three different resistors, namely resistor 324A, and two resistors 334A, 338A of the biasing element. The opposing terminal of resistor 324A connects to capacitor 328A, which in turn connects to ground as shown. The resistor 316A and capacitor 320A form one impedance element of the DC block, and the resistor 324A and capacitor 328A form the second impedance element of the DC block.

Biasing resistor 334A of the biasing element also connects to a supply voltage node Vcc while biasing resistor 338A connects to a ground terminal as shown. An amplifier section 230 connects to the biasing resistors 334A, 338A and is configured to amplify a received signal.

The resistors 304, 308 establish the low frequency input impedance. Resistors 304, 308 in conjunction with resistors 316A and 324A (and resistors 316B and 324B) establish the high frequency input impedance. In this embodiment, the resistor 316A and capacitor 320A form a first capacitive element, and the resistors 324A and capacitors 328A for a second capacitive element and operate as a capacitor divider network to block DC signal components while also passing the signal in the frequency band of interest, such as from 1 MHz or lower (100 KHz) to 40 to 50 GHz or higher.

In response to DC or low frequency signal, capacitors 320A appears as an open circuit thereby preventing DC signal components from reaching the biasing elements and the capacitive element group 324A, 328A. As a result, the low frequency impedance looking into inputs 208A, 208B is determined by the resistors 304, 308, which in one embodiment is configured to be 100 ohms and, in another embodiment, to be 50 ohms. In response to a high frequency signal, the capacitors 320A, 328A appear as short circuits thereby passing the input signal to the amplifier section 230. A voltage divider may occur in some embodiments but in other embodiments the full magnitude of the input signal is provided to the amplifier 230. This voltage divider may increase linearity and thus in certain embodiments this is a further benefit of the present innovation based on this additional flexibility. The resistors 304, 308 are still part of the circuit for high frequency signals and establish part of the impedance matching. The high frequency input impedance match for the input leg 208A appears as the resistor 304 in parallel with resistor 316A in series with resistor 324A, or Z_{208A}=R₃₀₄∥(R_{316A}+R_{324A}). A similar relationship holds for input 208B and resistors 308, 316B, and 324B where Z_{208B}=R₃₀₈∥(R_{316B}+R_{324B}). A specific embodiment of this could be if R₃₀₄=100Ω, R_{316A}=50Ω, and R_{324A}=50Ω, in which Z_{208A}=100Ω∥(50Ω+50Ω)=50Ω.

FIG. 3B is a circuit level diagram of an example embodiment of an integrated circuit located coupling capacitor arrangement for a single ended signal. As compared to FIG. 2A, similar elements are labeled with identical reference numbers. This embodiment is a single-ended configuration and as such, a single input 208A is provided. The impedance matching element 312 may comprise any combination of elements, active or passive, to match the input impedance of driver to a data source. In this embodiment the impedance matching element 312 is a capacitor. In other embodiments, other single ended configurations are possible that also benefit from an integrated voltage divider network that blocks DC signal components to avoid use of external capacitors.

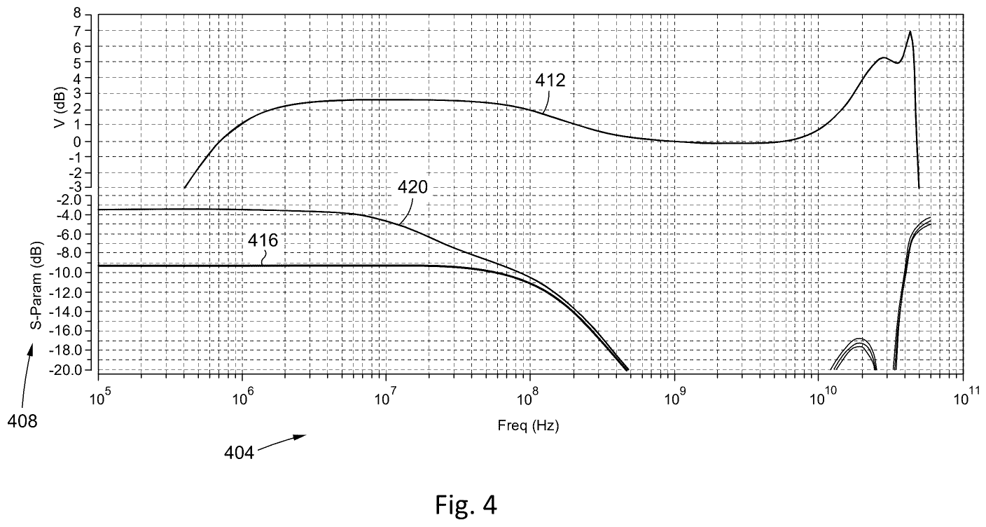

FIG. 4 illustrates a signal plot showing the performance of the embodiment of FIGS. 3A and 3B. In this plot the horizontal axis 404 represents frequency and the vertical axis 408 represents voltage ratios in dB. Signal line 412 represents the signal passing through the integrated circuit located coupling capacitors. As can be seen, the circuit has a good AC response at low frequencies, passing signals as low as 400 kHz (−3 dB cutoff) in this embodiment. Thus, this innovation achieves the goal of passing low frequency components in the frequency band of interest while blocking DC signal components at frequencies below the band of interest. Thus, the system serves as a successful signal block using the capacitive divider network described herein without the need for a large external blocking capacitor. Signal plot 416 represents the return loss of the capacitive structure and impedance matching features of the innovation shown in FIGS. 2A and 3A for differential signals/structure. Signal plot 420 represents the return loss of the capacitive structure and impedance matching features of the innovation shown in FIGS. 2B and 3B for singled ended signals/structure.

A low return loss is preferred and is an indication of the quality of the impedance matching. As can be seen, the return loss S11 is acceptable at low frequency, passing about 90% of the signal power and reflecting about 10% (reflection coefficient S11 is −10 dB or 1/10th of the incoming power), while being very low at higher frequencies. Thus, this innovative design also performs well from a return loss perspective.

Also disclosed is an integrated circuit AC coupling circuit arrangement with a matching network including an adjusted component ratio combined and a high impedance emitter follower stage. One challenge presented in prior art designs is that for most drivers and transimpedance amplifiers (TIAs) used in data center applications, the low-frequency cut-off is preferably lower than about 150 KHz to avoid a performance penalty, such as lower bandwidth. In addition, the driver is also required or preferred to have an integrated on-chip DC blocking capability so that the module can be implemented without the bulky and lossy off-chip DC blocking capacitors. As is understood, off-chip DC blocking capacitors undesirably increase the size and costs of a module.

However, achieving lower than 150 KHz lower cut-off frequency with on-chip DC blocking cap is very challenging due to the capacitor size limitation inherent in circuit integration processes. For example, most conventional drivers with an on-chip DC blocking cap have 600 KHz to 3000 KHz low-frequency cut-off, which does not meet the customers' specifications. As a result, circuit designs must accept a performance penalty or include an off-chip DC blocking capacitor outside the driver, neither of which are ideal solutions.

To overcome the drawback of the prior art and provide additional benefits, disclosed is a new design and method that combines both an on-chip integrated AC coupling network with a high impedance emitter follower (EF) stage to achieve extremely low-frequency cut-off. The new design provides a drastic improvement over the prior by providing 60 KHz low-frequency cut-off point, without increasing the chip size and insertion losses. This design avoids the bulky off-chip DC blocking capacitor without incurring a performance penalty.

In one embodiment, the AC coupling network consists of series and parallel connected resistors and capacitors. Due to the size limitation, the AC coupling network can achieve around 600 KHz low frequency cut-off in most cases.

In one embodiment, the emitter follower stage employs a current source bias at the base of the transistor. This current source provides a very high impedance node. This high impedance input, when combined with the AC coupling network, can push the low-frequency cut-off down to 60 KHz or even lower. This new design technique can meet the stringent specifications for low frequency cut off without changing the gain, power consumption, linearity, or chip size.

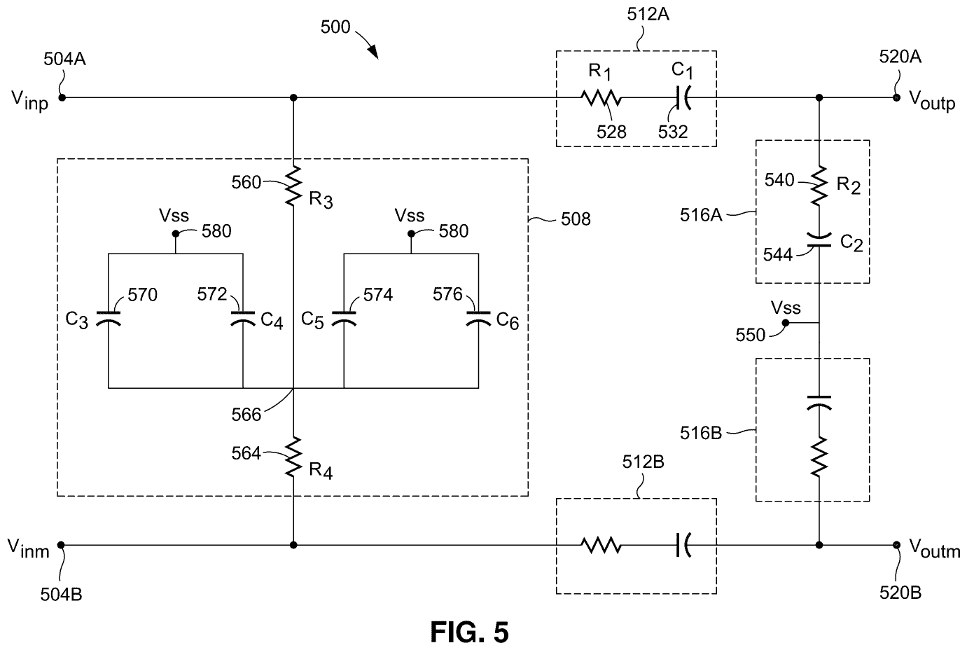

FIG. 5 illustrates an example embodiment of a coupling network that achieves the benefits described above when combined with the emitter follower stage disclosed herein. The circuit shown in FIG. 5 is one exemplary design layout, and as such, other configurations are possible and contemplated. This example embodiment is configured as a differential circuit but one of ordinary skill in the art would understand how to modify it into a single-ended embodiment.

As shown in FIG. 5, first and second input nodes 504A, 504B are configured to receive a differential input signal. This input signal may be received over a transmission line, such as from an amplifier/driver/TIA type device. The inputs are referenced as Vinp and Vinm. The input signal is presented to first impedance matching elements 512A, 512B and an impedance matching interconnect 508. The positive path first impedance matching element 512A, in the positive path comprises a resistor R1 528 in series with a capacitor C1 532. The other first impedance matching element 512B, referred to as the negative path first impedance matching element is configured similarly.

The opposing terminals of the first impedance matching elements 512A, 512B connect to the first and second output nodes 520A, 520B which present the differential output signals Voutp and Voutm as the outputs from the coupling network. Connected between the output nodes 520A, 520B are second impedance matching elements 516A, 516B. The positive path second impedance matching elements 516A is associated with the positive signal path, while the negative path second impedance matching elements 516B is associated with the negative signal path.

In this embodiment, the positive path second impedance matching elements 516A comprises a resistor R₂ 540 in series with a capacitor C₂ 544. The negative path second impedance matching elements 516B is similarly configured as shown. Between the positive path second impedance matching elements 516A and the negative path second impedance matching elements 516B is a ground node or virtual ground node Vss 550.

The first impedance matching elements 512A, 512B and the second impedance matching elements 516A, 516B are configured in relation to one another, and the values selected for the elements therein may have the following relationship such that the ratio of R₁/R₂=C₁/C₂ such that R₂ is larger than R₁. The structure of elements R1, R2, C1, C2 function as a voltage divider, resistive network, capacitive network, or capacitor divider network.

This overcomes a drawback of the prior art. In the prior art, the value of R₁ was set as being equal to R₂, which resulted 6 dB of signal loss (loss of gain) due to 50% of the input signal power passing to a ground such as through elements 324A, 328A as shown in FIG. 3A. This undesirably reduced the gain of prior art circuits. By setting R₂ larger than R₁, power output is increased at the output nodes 520A and 520B due to a larger percentage or portion of the input signal being sent to the output node 520 and less passing to the ground node 550. As a result, the gain will decrease by only about 1.5 dB. This is a significant benefit over the prior art. This results in an improved return loss value as compared to the prior art and extends the low-frequency cut-off value as discussed above.

The impedance matching interconnect 508 connects between the first and second input nodes 504A, 504B as shown. The function of the impedance matching interconnect 508 is for impedance matching the input impedance looking into the coupling network 500 to the upstream circuit portion which connects to the input nodes 504A, 504B. Numerous various elements may be upstream and provide a signal to the input nodes 504A, 504B such as but not limited to a transmission line (integrated circuit configuration) or an amplifier, driver, TIA, or other element(s) that would benefit from the coupling network with wide bandwidth, a low cut-off frequency, low return loss, and matching input impedance. The connection may occur through wirebonds, bump chip connections, or any other electrically conductive connection.

In one embodiment, the impedance matching interconnect 508 comprises series connected resistors R₃ 560 and R₄ 564. One or more bypass capacitors C₃-C₆ 570, 572, 574, 576 connect at a node 566 that is located between the resistors R₃ 560 and R₄ 564. The one or more bypass capacitors C₃-C₆ 570, 572, 574, 576 short high-frequency noise to the ground node Vss 580. The values of R₃ 560 and R₄ 564 may be selected to establish an input impedance for the coupling network 500 to optimize return loss, such that the input impedance may match the output impedance of an upstream element. In one embodiment, the value of (R1+R2) in parallel with R3 is 50 ohms for the positive signal path. The values of R₃ 560 is selected to meet this criteria. As such, the value of R₃ may be set to be generally equal to R1+R2. Thus, if the values of R1 and R2 are 50 ohms and R3 is 100 ohms, the resulting input impedance value would be ˜50 ohms. These values are exemplary only, and other values may be selected. The value of R₄ 564 would also be selected to satisfy the same relationship but for the negative signal path.

Other arrangements of the circuit elements of the impedance matching interconnect 508 are contemplated and within the scope of the claims that follow. In some embodiments, the impedance matching interconnect 508 may be omitted.

The discussion above as it relates to FIG. 5 applies to single-ended configurations and differential mode configurations. However, for differential mode configurations, for common mode signals, the relationship between the values of R₃ 560 and R₄ 564 are less critical, but it is preferred to have R₃ and R₄ selected to establish an 8 to 10 dB minimum return loss. These are ranges, and the values could vary depending on the application but should be in a reasonable range to avoid undesirable level of return loss. It is contemplated that for non-common mode signals and configurations, the return loss can be in the range of 15 to 20 dB.

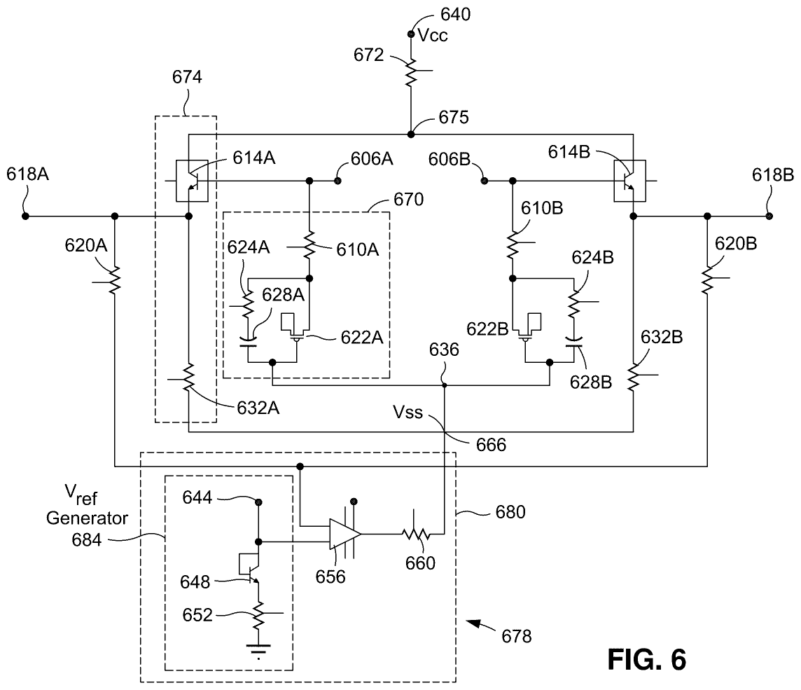

FIG. 6 illustrates an exemplary emitter follower circuit with an internal biasing circuit, collectively configured to follow the matching network of FIG. 5. It is also contemplated that the emitter follower (EF) circuit shown in FIG. 6 may be configured as a stand-alone circuit without connection to a matching network. This is but one possible EF circuit configuration, and as such it is contemplated that other circuit layouts are possible without departing from the scope of the claims that follow.

Turning to the elements of FIG. 6, the left-hand side and the right-hand side of the circuit are mirror replicas configured as a differential circuit. Only one side may be utilized for a single-ended configuration. To aid in understanding and to reduce duplication, only the left-hand side of the circuit is described below, with the understanding that the arrangement and function of the right-hand side would be the same. An input node 606A connects to the matching network of FIG. 5. The input node 606A also connects to a biasing circuit 670 and the EF circuit 674.

The EF circuit 674 includes a transistor 614A and resistor 632A such that the input connects to the base terminal of the transistor, while the resistor connects to the emitter terminal. An output node 618A connects to the emitter terminal of the transistor 614A. The opposing terminal of the resistor 632A connects to a ground node Vss 666. The collector terminal of the transistor 614A connects to a supply voltage node 674. In this embodiment, the supply voltage node 674 connects through a step-down resistor 670 to a primary supply Vcc node 640. The EF circuit 674 functions as a buffer between the matching network and the downstream element, such as but not limited to an amplifier, variable gain amplifier (VGA), or driver. As a benefit of this design, the input impedance looking into the EF circuit 674 is very high.

The bias circuit 670 provides a bias current and/or voltage to the EF circuit. The bias circuit 670 provides the DC bias current to the input node 606A of the EF circuit 674. In this embodiment, the bias circuit 670 comprises a bias FET 622A connected in parallel with a series-connected resistor 624A and capacitor 628A.

The bias circuit 670 connects to the input node 606A, through a step-down resistor 610A. and also connects to a bias control voltage node 636. A base terminal of the bias FET 622A receives the bias control voltage such that the bias control voltage determines (sets) the bias current for the bias circuit 670. The generation and source of the bias control voltage are discussed below.

As a benefit to this design, the input impedance looking into the bias circuit 670 is very high. This results in the input signal power flowing primarily to the low impedance EF circuit 674 and not into the high input impedance bias circuit. This optimizes return loss.

Turning now to the bias control signal generator 680, shown at the bottom of FIG. 6, which generates the bias control voltage that is provided to node 636. The bias control signal generator 680 comprises a Vref generator 684, a comparator 656, and a resistor 660. The resistor 660 connects the output of the comparator 656 to node 636 and functions to stabilize the output of the comparator 656 and isolate the bias control signal generator 680.

The Vref generator 684 comprises a bandgap supply voltage node 644, a diode-connected NPN device 648, and a resistor 660, all of which are connected in series, as shown. The bandgap supply voltage node 644 supplies a supply voltage that does not vary over temperature. The device 648 connects to bandgap supply voltage node 644, as shown in FIG. 6. The Vref generator 648 has a behavior that varies over temperature, thereby imparting a temperature-dependent behavior into the output of the Vref generator 684. The opposing terminal of device 648 connects to a resistor 652, which in turn connects to a ground node.

In this embodiment, the comparator 656 comprises an operational amplifier that generates a difference signal in relation to its two inputs. One input to the comparator 656 is from the Vref generator 684, and the other input is a voltage generated by a sensing resistor 620A. The sensing resistor 620A also connects to the output node 618A. The output of the comparator 656 is provided to node 636, which connects to the bias circuit 670 to provide bias control signal to the bias circuit.

In operation, an input signal from the matching network of FIG. 5 or other signal source, is provided to the input node 606A. From node 606A, the input signal is presented to the base of the EF circuit transistor 614A. The bias circuit 670 provides a DC bias current to the EF circuit 674. The bias current value is determined by the output signal from the comparator 656 (which passes through node 636) and is adjusted for temperature. The EF circuit 674 establishes a high input impedance. The output of the EF circuit 670 is presented on the output node 618A.

The bias signal generator 680, in operation, utilizes the bandgap supply voltage, which does not vary over temperature, from node 644, in combination with the transistor 648 to generate a voltage which does vary over temperature. This temperature dependent signal is the reference voltage. The value of the reference voltage is selected to establish the desired bias current for the EF circuit 674. Using the reference voltage, the bias signal generator generates a bias control signal by comparing the reference voltage to the DC value in the output signal, as presented through the sending reference. The comparator (op-amp) 656 performs this comparison. The comparator 656 outputs the bias control voltage, such that over time the bias control voltage is driven to be at the same value as the selected reference voltage (from Vref generator 684) due to the feedback loop established through the bias circuit 670, EF circuit 674, the sensing resistor 620A, and into the second input of the comparator 656. The reference voltage (from Vref generator 684) varies over temperature to account for changes in temperature that would otherwise interfere with the ideal biasing of the EF circuit.

The right-hand side of the differential circuit shown in FIG. 6 is configured and operates in the same manner as the above-described left-hand side of the circuit. The scope of the invention is not limited to this particular layout or process and one of ordinary skill in the art would understand how to adapt this circuit to other processes or environments.

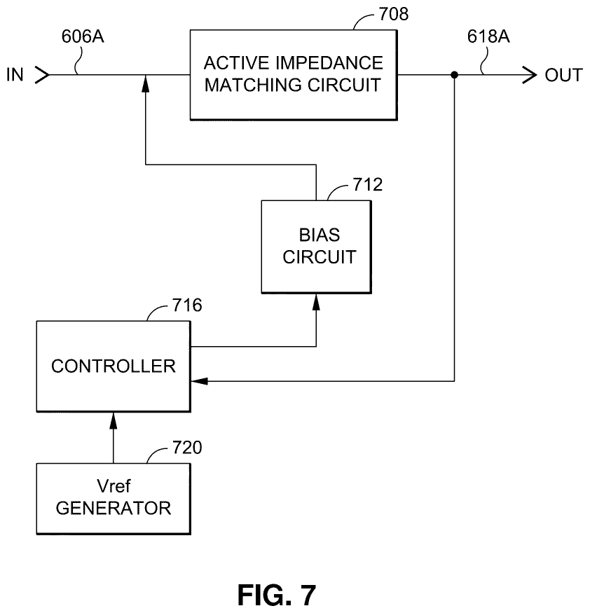

FIG. 7 illustrates a generalized block diagram of a single-ended version of the circuit of FIG. 6. In this embodiment, the input node 606A is configured to receive an input signal. The input signal is provided to an active impedance matching network 708, which establishes a high input impedance and a wide bandwidth capability. A bias circuit 712 provides a DC bias to the active impedance matching circuit 708. The output of the active impedance matching circuit 708 is provided on node 618A and is fed back to a controller 716. The controller 716 compares the output signal, such as the DC voltage level of the output signal, to a reference voltage from a reference voltage generator 720. Based on the difference between these input signals, the output of the bias circuit is adjusted. In one embodiment, if the DC voltage level of the output signal is greater than the reference voltage, then the controller 716 provides a bias control signal to the bias circuit that reduces the bias signal presented to the active impedance matching circuit. Conversely, if the DC voltage level of the output signal is less than the reference voltage, then the controller 716 provides a bias control signal to the bias circuit that forces an increase in the bias signal presented to the active impedance matching circuit 708. The controller 716 may include one or more temperature-dependent elements configured to adjust the bias signal based on temperature. It is also contemplated that adjustment to the bias signal may be made based on age related changes in the circuit. In one embodiment, a look-up table is used to store different values to adjust the bias signal based on the age of the system.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

While various embodiments of the invention have been described, it will be apparent to those of ordinary skill in the art that many more embodiments and implementations are possible that are within the scope of this invention. In addition, the various features, elements, and embodiments described herein may be claimed or combined in any combination or arrangement.

What is claimed is:

1. A system configured as part of an integrated circuit to block DC components from an amplifier comprising:
a matching network comprising:
an input configured to receive an input signal, the input signal having a DC component;
a voltage divider network having a network input, a network output, at least one resistor, and at least one capacitor, wherein the network input is configured to receive the signal having a DC component such that the voltage divider network blocks the DC component to generate a network output signal that is provided to the network output;
an emitter follower (EF) circuit comprising:
an EF input configured to receive the network output signal;
an EF device configured to process the network output signal to generate and present an EF circuit output signal on an EF output;
a biasing circuit configured to generate a bias signal for the EF device, such that the bias signal has a value that is controlled by a bias control signal; and
bias control signal generator configured to compare the EF circuit output signal to a reference voltage, and generate the bias control signal.

2. The system of claim 1 wherein the voltage divider network comprises a first impedance element and a second impedance element.

3. The system of claim 2 wherein the first impedance element and the second impedance element comprise a resistor in series with a capacitor.

4. The system of claim 1 wherein the biasing circuit generates a temperature-dependent current that biases the EF circuit.

5. The system of claim 4 wherein the biasing circuit comprises a field effect transistor in parallel with a series connected resistor and capacitor.

6. The system of claim 1 wherein the matching network and the EF circuit are duplicated to create a differential circuit.

7. The system of claim 1 wherein the bias control voltage generator comprises a temperature-dependent reference voltage generator configured to generate the reference voltage and a comparator configured to compare the reference voltage to a feedback signal from the EF circuit output, and based on the comparison, generate the bias control signal.

8. An impedance matching system configured as part of an integrated circuit for a differential pair environment to couple differential inputs to an amplifier, the system comprising:
a first path comprising:
a first path matching network that includes a first path input, a first path first impedance element, a first path second impedance element, and an output such that the first path first impedance element blocks a DC component of a first path input signal;
a first path emitter follower circuit having an input connected to an output of the first matching network and an output configured to connect to an amplifier, the first path emitter follower circuit includes a biasing circuit that generates a biasing signal that compensates for changes in circuit behavior over temperature;
a second path comprising:
a second path matching network that includes a second path input, a second path first impedance element, a second path second impedance element, and an output such that the second path first impedance element blocks a DC component of a second path input signal;
a second path emitter follower circuit having an input connected to an output of the second matching network and an output configured to connect to the amplifier, the second path emitter follower circuit includes a biasing circuit that generates a biasing signal that compensates for changes in circuit behavior over temperature; and
an impedance matching element connected between the first path input and the second path input, the impedance matching element configured to match an input impedance of the impedance matching system to a source of the first path input signal and the second path input signal.

9. The system of claim 8 wherein the first path first impedance element comprises at least one resistor and at least one capacitor.

10. The system of claim 9 wherein at least one resistor and the at least one capacitor are in series.

11. The system of claim 8 further comprising, in each of the emitter follower circuits, a bias control signal generator.

12. The system of claim 11 wherein the bias control signal generator comprises a reference voltage generator, configured to generate a reference voltage, and a comparator configured to generate a bias control signal based on the comparison.

13. The system of claim 12 wherein the comparator compares the reference voltage to a feedback signal from one or more sensing resistors, the one or more sensing resistors connected to the outputs of the first path emitter follower circuit and the second path emitter follower circuit.

14. The system of claim 8 wherein the impedance matching element comprises at least one resistor and at least one capacitor such that the at least one capacitor is connected to ground.

15. A method for coupling an input signal to a driver, and blocking DC components of an input signal comprising:
receiving the input signal from a data source, the input signal having a DC component;
providing the input signal to a first impedance element, the first impedance element configured as part of an integrated circuit;
blocking the DC component of the input signal with the first impedance element;
providing an output from the first impedance element to a second impedance element, the second impedance element configured as part of the integrated circuit;
establishing the input impedance with the second impedance element and the first impedance element to create an impedance matched network that create an impedance matched signal;
providing the impedance matched signal to an emitter follower circuit and buffering the impedance matched signal to create a buffered output signal, the emitter follower circuit operation further comprising:
establishing a temperature-dependent biasing signal to maintain a temperature-dependent biasing signal; and
providing the biasing signal to the emitter follower circuit.

16. The method of claim 15 wherein the input signal is a differential signal pair comprising a first signal on a first path and a second signal on a second path, the second path generally identical to the first path, the first and second path each having the first impedance element and the second impedance element and further comprising matching the input impedance of the driver to a data source with an impedance matching element connected between the first path and the second path.

17. The method of claim 15 wherein the first impedance element and the second impedance element each comprise at least one resistor and at least one capacitor connected in series.

18. The method of claim 15 wherein the impedance matching element comprises an interconnect between the first path and the second path, the interconnect having two or more resistors and two or more capacitors, the two or more capacitors connected between the interconnect and ground.

19. The method of claim 15 further comprising:
providing a feedback signal representing a scaled version of the buffered output signal to a bias control signal generator;
comparing the feedback signal to a reference voltage;
based on the comparing, generating a bias control signal, such that the bias control signal is temperature-dependent; and
providing the bias control signal to a biasing circuit in the emitter follower circuit, the bias control signal controlling the value of the temperature-dependent biasing signal.

20. The method of claim 19 wherein the comparing is performed by an operational amplifier and the reference voltage is generated by a reference voltage generator that generates the reference voltage.
